(19) United States
(12) Patent Application Publication
(10) Pub. No.: US 2024/0356341 A1
(43) Pub. Date: Oct. 24, 2024

(54) BATTERY MANAGEMENT SYSTEM

(71) Applicant: Commonwealth Scientific and Industrial Research Organisation, Australian Capital Territory (AU)

(72) Inventor: Andrew TREZISE, Australian Capital Territory (AU)

(73) Assignee: Commonwealth Scientific and Industrial Research Organisation, Australian Capital Territory (AU)

(21) Appl. No.: 18/683,527

(22) PCT Filed: Aug. 8, 2022
(86) PCT No.: PCT/AU2022/050857

§ 371 Date: Feb. 14, 2024

(30) Foreign Application Priority Data
Aug. 16, 2021 (AU) 2021902550

(51) Int. Cl. H02J 7/00

(52) U.S. Cl. CPC H02J 7/00047; H02J 7/00041; H02J 7/0025; H02J 7/005; H02J 2207/20; H02J 2207/30

(57) ABSTRACT

The present invention is directed to a battery management system for managing one or more second-life battery packs. The system comprises one or more buffer modules. Each buffer module is configured for coupling to a corresponding battery pack. Each buffer module is operatively configured to determine a type of battery pack upon detection of the corresponding battery pack being coupled thereto. Each buffer module includes a battery pack controller for controlling charge and discharge cycles for each battery pack based on the type of battery pack as determined by the corresponding buffer module. Each buffer module includes a bi-directional DC to DC converter for converting a voltage input from the corresponding battery pack to a predetermined system output voltage.

### RELATED APPLICATIONS

This application claims priority from Australian Application No. 2021902550 filed on 16 Aug. 2021, the contents of which are to be taken as incorporated herein by this reference.

### TECHNICAL FIELD

The present invention relates to a battery management system. In particular, embodiments of the present invention relate to a battery management system for second-life batteries.

### BACKGROUND OF INVENTION

The continued growth in electric vehicles (EV) and hybrid electric vehicles (HEV) in recent years has resulted in an increase in the availability of second-life batteries, and the emergence of a new power sector involving power storage using second-life batteries.

When an EV or HEV battery reaches the end of its useful first life, manufacturers can either dispose of the ex-service battery, recycle the valuable metals, or reuse it in a second-life application. In most cases, these batteries are still able to perform sufficiently to serve less-demanding energy-storage applications even after they no longer meet EV/HEV performance standards.

Some suitable energy-storage applications for second-life batteries include providing reserve energy capacity to maintain a utility's power reliability, deferring transmission and distribution investments, and storing renewable power for use during periods of scarcity. However, several challenges are present in repurposing second-life batteries. For example, different battery designs on the market vary in size, electrode chemistry and other characteristics. According to some forecasts, up to 250 new EV models could exist by 2025. As each battery is designed to suit a particular EV model, the lack of standardisation causes complexities in repurposing the batteries for second-life applications.

Embodiments of the invention may provide a battery management system and a battery system which overcomes or ameliorates one or more of the disadvantages or problems described above, or which at least provides the consumer with a useful choice.

A reference herein to a patent document or any other matter identified as prior art, is not to be taken as an admission that the document or other matter was known or that the information it contains was part of the common general knowledge as at the priority date of any of the claims.

### SUMMARY OF INVENTION

According to one aspect of the invention, there is provided a battery management system for managing one or more second-life battery packs, the system comprising
one or more buffer modules, each buffer module for coupling to a corresponding battery pack, wherein each buffer module is operatively configured to determine a type of battery pack upon detection of the corresponding battery pack being coupled thereto, and
each buffer module including a battery pack controller for controlling charge and discharge cycles for each battery pack based on the type of battery pack as determined by the corresponding buffer module,
wherein each buffer module includes a bi-directional DC to DC converter for converting a voltage input from the corresponding battery pack to a predetermined system output voltage. Some existing solutions rely on pre-testing or the sorting of ex-service vehicle batteries to select the batteries that are closely matched in characteristics before using them in a single battery system.

In the present invention, each buffer module is capable of automatically determining the type of battery pack once the battery pack is connected. Each buffer module also dynamically carries out charge and discharge cycles for the battery pack based on the detected battery pack type. Advantageously, extensive pre-testing, sorting, and actively matching characteristics of the ex-service batteries prior to deployment in the battery system is not required. Embodiments of the present invention is capable of utilising different types of battery packs, having multiple different chemistries in the same system.

In one embodiment, each battery pack controller is operatively configured to determine one or more battery parameters associated with the corresponding battery pack to determine the type of battery pack. Any suitable battery parameters may be used to determine the type of battery pack. In one example, the battery parameters may include any one or more of an output voltage range of the corresponding battery pack, and a number of battery modules in the corresponding battery pack.

The converter in the buffer module may be configured to receive a voltage input from the corresponding battery pack having an operating voltage range of generally between 14 to 36 volts. Moreover, the converter may be configured to provide a predetermined system output voltage of about 48 volts DC from the corresponding battery pack. In addition, the converter may be configured to provide a predetermined power output of about 500W from the corresponding battery pack.

In one embodiment, there is provided a battery management system for managing one or more second-life battery packs, the system comprising a common DC bus and one or more buffer modules. Each buffer module may comprise a bi-directional DC-to-DC converter. The bi-directional DC-to-DC converter may have a first port and a second port. The first port may be operably coupled to the common DC bus, and the second port may be adapted for connection to a second-life battery pack via a battery interface.

The battery management system may further comprise a battery pack controller operatively configured for the control and monitoring of the DC-to-DC converter. For example, the battery pack controller may be configured to implement one of a plurality of charge and discharge profiles, each profile corresponding to a second-life battery pack having a specific battery pack chemistry and/or topology. In some embodiments, the battery management system may include two or more buffer modules, each buffer module including a bi-directional DC-to-DC converter having a second port adapted for connection to a second-life battery pack as previously described. In this embodiment, the battery management system may be configured for coupling to two or more second-life battery packs, each second-life battery pack having a different battery pack chemistry and/or topology to one or more of the other second-life battery packs coupled to the battery management system. The battery management system may further include sensing circuitry configured to receive a signal from the battery interface to the battery pack controller for the determination of the battery pack type and corresponding charge/discharge profile.

In another embodiment, the DC-to-DC converter could be replaced by a bi-directional micro-inverter and charger. In this embodiment, each buffer module may directly couple to the AC grid, thereby removing the need for a separate inverter. Accordingly, in addition to determining the control parameters, the master system controller may also monitor AC voltage, and grid import and export current.

In one embodiment, the converter may be coupled to a discharge resistor for discharging a corresponding battery pack at end of life. Advantageously, system may further provide the ability to completely discharge any battery module or battery pack to zero and recover all the residual energy at the end of second-life service, to ensure safe handling and processing for recycling.

Typically, each battery pack includes a plurality of battery modules. The battery management system may further comprise one or more interface modules, each interface module being configured to interface with the battery modules of a corresponding battery pack.

Each interface module may include a plurality of switching assemblies for connecting the battery modules in each corresponding battery pack to the corresponding buffer module. The battery pack controller may be operatively configured to sequentially determine whether each battery module within the corresponding battery pack is defective, and disconnecting the battery module from the buffer module upon determining that the battery module is defective.

The battery pack controller may make the determination of whether each battery module is defective in any suitable manner, for example by measuring module output, capacity and/or any other operating parameter. In one embodiment, the battery pack controller may determine whether each battery module is defective by determining whether the battery module has an output voltage within a predetermined voltage tolerance range.

Typically, the battery pack controller determines the defective battery modules during a start-up routine when the corresponding battery pack is connected to the buffer module for the first time. Once the battery pack controller determines that a particular battery module is defective, the battery pack controller excludes the defective battery module during charging and discharging operations.

In some embodiments, the battery pack controller may be operatively configured to sequentially charge or discharge each battery module one at a time. During operation, the interface module constantly switches between the battery modules sequentially within each battery pack. This means that at any point in time during a charge or discharge cycle, only one battery module within each battery pack is connected to the corresponding buffer module. Accordingly, in this embodiment, each buffer module automatically and sequentially connects only one battery module at a time during charge or discharge, thereby removing any need to closely match parallel battery characteristics and isolating the effect of depleted cells on the overall energy storage capacity.

In some embodiments, the interface modules may provide a signal to the buffer module for the purpose of determination of a battery type of a corresponding battery pack. In some embodiments, each interface module may be associated with a voltage divider circuit. The voltage divider circuit may be provided to facilitate determining the type of battery pack connected to a corresponding buffer module. The voltage divider circuit may form part of the buffer module and interface module. A battery voltage detected via the voltage divider may be indicative of the type of battery pack connected to the corresponding buffer module.

The battery management system may be configured to connect two or more battery packs in parallel. In addition, the battery management system may be configured to connect each battery pack to the common DC bus via the corresponding buffer module.

In one embodiment, the battery management system may further comprise one or more capacitors coupled to the common DC bus for holding a voltage on the common DC bus generally constant while switching between battery modules within each battery pack. Any suitable capacitors may be used. In one embodiment, one or more supercapacitor are coupled to the common DC bus.

The battery management system may further include a system controller for determining control parameters for communication with each battery pack controller based on voltage and current values detected on the common DC bus. Typically, the voltage and current values detected on the common DC bus represent the demand of one or more connected external loads, the available power in the battery packs, and/or any input power from external sources such as the grid, and/or a renewable power system such as a solar PV system.

In one example, the control parameters may include any one or more of: an operating state of the battery management system, the operating state including a charge state, a discharge state and an idle state, a charge power setpoint for each battery pack controller, and a discharge power setpoint for each battery pack controller.

In some embodiments, each battery pack controller may be operatively configured to detect an operating fault associated with the corresponding battery pack or corresponding buffer module. Upon determination of a fault, the battery pack controller may assign a fault status for the corresponding buffer module upon detection of the operating fault. During operation, the system controller may be operatively configured to exclude the buffer module associated with a fault status in use.

In one embodiment, the system controller is a master controller, and each battery pack controller is a slave device for receiving control signals from the master controller. Each slave device may be configured to sample the corresponding battery pack and update the master controller with battery parameters associated with the corresponding battery pack. In this embodiment, the slave devices are configured to automatically determine the type of each corresponding battery pack, and sequentially connect and disconnect each battery module within the corresponding battery pack during charging and discharging. The master controller may be configured to determine appropriate control parameters based the available power and capacity of the battery packs within the system to match external connections of the system.

In an alternative embodiment, one of the buffer modules may include a master controller, and each of the other buffer modules may include a slave device. In this embodiment, the master controller may be a bi-directional micro-inverter for controlling charging and discharging operations of the corresponding battery pack, and determining control parameters for the slave devices based on the external AC load or input.

According to another aspect of the invention, there is provided a battery system comprising a battery management system as described herein, and one or more battery packs for coupling to the one or more buffer modules of the battery management system.

According to another aspect of the invention, there is provided a battery system comprising
a plurality of battery packs,
a plurality of buffer modules, each buffer module being configured for coupling to a corresponding battery pack, wherein each buffer module is operatively configured to determine a type of battery pack upon detection of the corresponding battery pack being coupled thereto,
each buffer module including a battery pack controller for controlling charge and discharge cycles for each battery pack based on the type of battery pack as determined by the corresponding buffer module, and
wherein each buffer module includes a bi-directional DC to DC converter for converting a voltage input from the corresponding battery pack to a predetermined system output voltage.

At least one of the battery packs in the battery system may have a differing battery pack chemistry and/or topology to one or more of the other battery packs in the battery system.

In order that the invention may be more readily understood and put into practice, one or more preferred embodiments thereof will now be described, by way of example only, with reference to the accompanying drawings.

### BRIEF DESCRIPTION OF DRAWINGS

FIG. 1 is a schematic diagram illustrating a battery system including a battery management system according one embodiment of the present invention.

FIG. 2 is a schematic diagram illustrating a battery interface module configured to fit a battery pack made up of ex-service Nissan Leap Lithium-ion battery units.

FIG. 3 is a schematic diagram illustrating a voltage divider system to facilitate the automatic detection of a type of battery pack connected to a buffer module of the battery management system.

FIG. 4 is a flow diagram illustrating operations of the system controller (master controller) to determine control parameters for the battery system based on external load requirements and/or power provided to the battery system.

FIG. 5 is a flow diagram illustrating a start-up routine for a battery pack controller (slave device) of the battery system to determine a type of battery pack connected thereto and to selectively connect or disconnect each battery module within the battery pack.

FIG. 6 is a flow diagram illustrating a main control loop for the battery pack controller (slave device). In this control loop, the battery pack controller determines parameters for sequentially charging and discharging each battery module within the battery pack.

### DETAILED DESCRIPTION

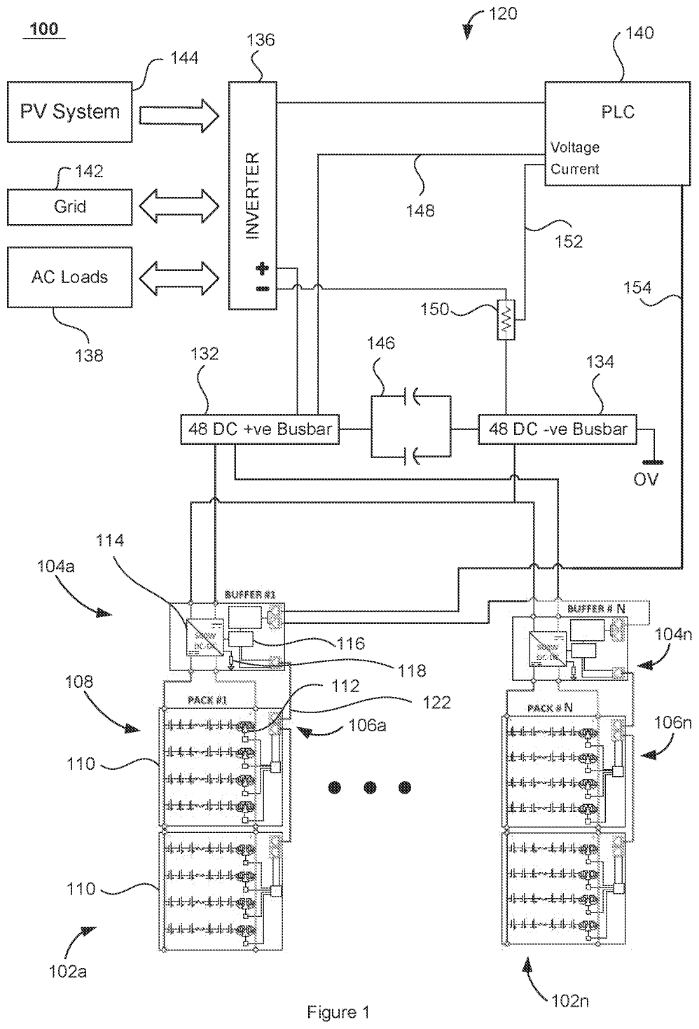

FIG. 1 illustrates a battery system 100 according to one embodiment of the invention. The battery system 100 includes a battery management system 120 for managing the operation of a plurality of second-life battery packs 102a to 102n connected to the battery system 100 in parallel. Whilst FIG. 1 only illustrates two battery packs 102a, 102n, it is understood that the battery system 100 can include any suitable number of battery packs depending on the power storage requirements of a particular application. For instance, a battery system for a campervan would typically include fewer battery packs than a battery system for a commercial retail and hospitality hub.

Each battery pack 102a to 102n (collectively referred to herein as 102) is connected to the battery management system 120 via a corresponding buffer module 104a to 104n (collectively referred to herein as 104) and a corresponding interface module 106a to 106n (collectively referred to herein as 106). In particular, each battery pack 102 includes a plurality of battery modules 108 arranged in parallel, and each battery module 108 includes a plurality of battery cells connected in series. In the specific non-limiting embodiment shown, each battery pack 102 represents two battery units 110. Each battery unit 110 represents a Toyota ex-service hybrid Nickel-Metal Hydride (NiMH) battery unit. Each battery unit 108 includes four battery modules 106 arranged in parallel.

Each buffer module 104 includes a bi-directional DC to DC converter 114 for converting a DC voltage from the battery pack 102 to a predetermined DC supply voltage and power output. In one embodiment, the converter is configured to receive a voltage input from the corresponding battery pack having an operating voltage range of roughly between 14 to 36 volts. The predetermined DC supply voltage is about 48 volts and the power output per battery pack is about 500 watts. The bi-directional DC to DC converter 114 also converts an available DC voltage from an external power source (e.g. the grid) to a suitable charging voltage to charge the battery pack 102 as discussed in further detail below.

The conversion of voltage and power from a wide input range to provide a predetermined voltage and power output via the bi-directional DC to DC converter allows the battery management system 120 to be configurable for use with any type of second-life battery packs, or even a mixture of different types of battery packs in a single battery system. In addition, the need to pre-test and match battery units prior to their adoption for use in a battery system can be avoided, thereby providing a more versatile, adaptable and cost effective second-life battery system.

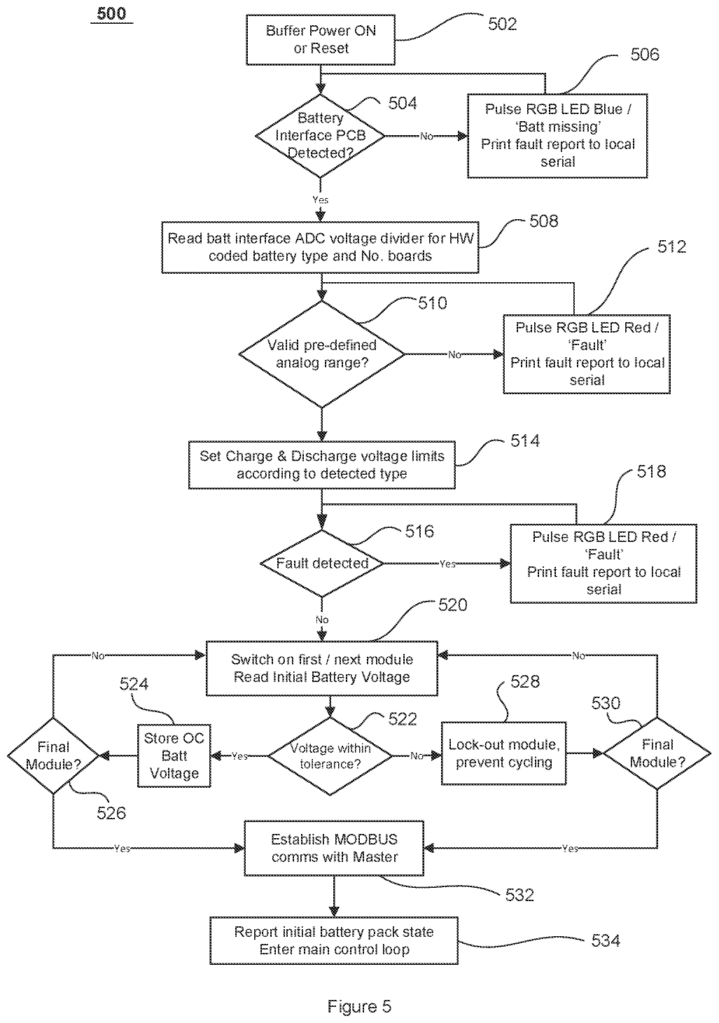

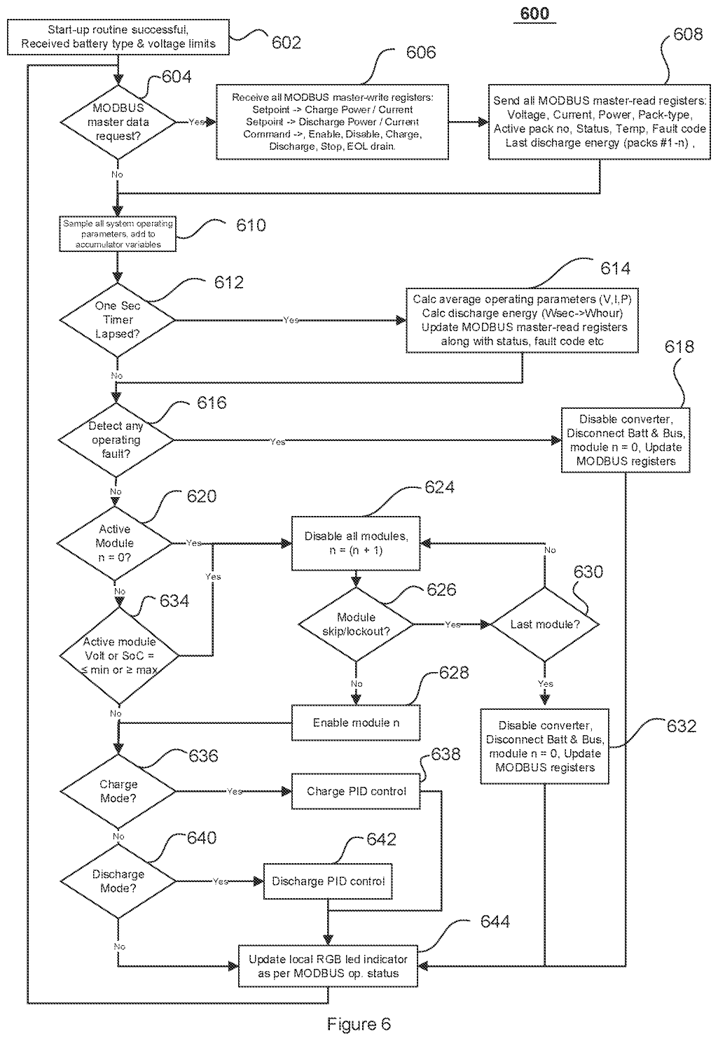

The buffer module 104 also includes a microcontroller (herein referred to as the battery pack controller 116) for controlling operation of the corresponding battery pack 102, including charging and discharging cycles for the battery pack 102. The specific operation of the buffer module 104 according to one embodiment of the invention will be discussed in further detail below with reference to FIGS. 5 and 6.

Each buffer module 104 also includes a discharge resistor 118 coupled to the bi-directional DC to DC converter for fully discharging the battery pack 102 at end of life. The battery management system 120 is therefore capable of completely discharging a battery pack for decommissioning.

The interface module 106 includes a plurality of switching assemblies 112. The switching assemblies 112 selectively connects a single battery module 108 from the each battery pack 102 for charging and discharging. Operation of the switching assemblies 112 to selectively connect and disconnect each one of the battery modules 108 is controlled by the battery pack controller 116 via digital communication channel 122. In particular, only one battery module 108 from the plurality of battery modules 108 within each battery pack 102 is connected to the corresponding buffer module 104 at any point in time.

Typically, the battery pack controller 116 is operatively configured to sequentially determine whether each battery module 108 within the corresponding battery pack 102 is defective, and selectively disconnecting the battery module 108 to the buffer module 104 upon determining that the battery module 108 is defective. In another embodiment, the battery pack controller 116 is operatively configured to sequentially determine whether each battery module 108 within the corresponding battery pack 102 is non-defective, and selectively connecting the battery module 108 to the buffer module 104 upon determining that the battery module 108 is non-defective. In one example, the battery pack controller 116 determines whether each battery module 108 is defective or non-defective by determining whether the battery module 108 has an output voltage within a predetermined voltage tolerance range.

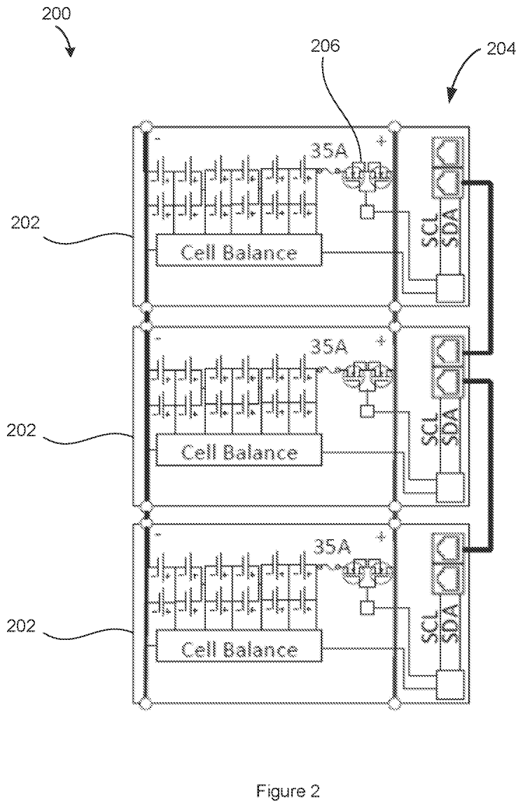

Whilst not shown in FIG. 1, the battery management system 120 can be used with any suitable type of second-life battery unit. For example, the battery management system 120 may include a plurality of ex-service Nissan Leaf Lithium-ion battery units. A battery pack 200 including three Nissan Leaf Lithium-ion battery units 202 is illustrated in FIG. 2. In this example, the interface module 204 includes a single switching assembly for each battery unit 202 to match the battery configuration of the Nissan Leaf Lithium-ion battery units.

Upon detection of a battery pack 102 or 200 being connected to a corresponding buffer module 104, the buffer module is capable of automatically determining the type of battery pack that has been connected. In particular, the battery pack controller 116 is operatively configured to automatically determine the type of battery pack connected to the corresponding buffer 104, for example by determining specific operating parameters of the battery pack. Once the type of battery pack is determined, the controller 116 controls the charging and discharging cycles for the corresponding battery pack 104 based on the determined type of battery pack.

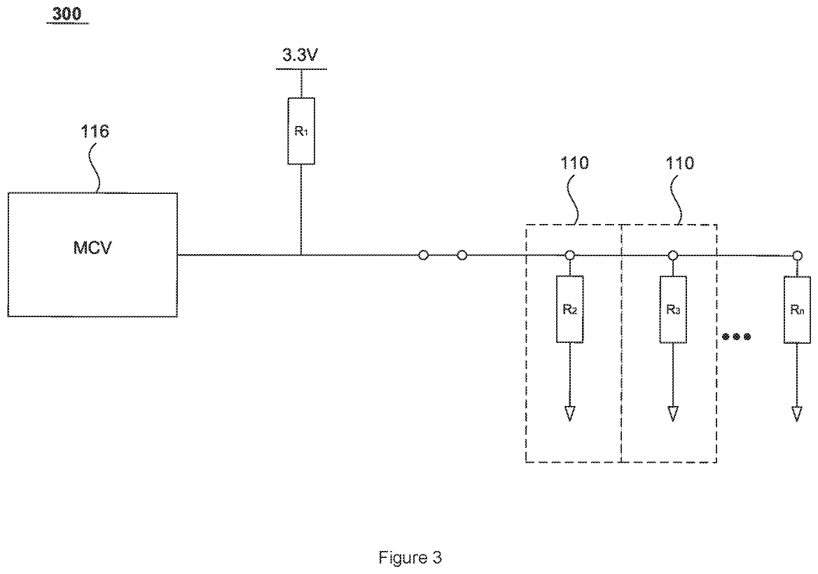

In one example, the specific operating parameters of the battery pack may include an output voltage range of the corresponding battery pack. As described below with reference to FIG. 3, the detected output voltage range of the battery pack can be used to determine certain battery pack characteristics, including the number of battery units connected in the pack. As the number of battery modules per battery unit is typically known once the type of battery unit is determined, the total number of battery modules available in the battery pack can also be determined.

Now referring to FIG. 3, which illustrates a voltage divider circuit 300 to facilitate determining the type of battery pack connected to a corresponding buffer module 104. In the embodiments shown in FIGS. 1 and 2, the voltage divider circuit 300 forms part of the buffer module 104 and interface module 106. The interface module 106 includes a resistor R₂, R₃ . . . Rₙ for each battery unit 110. During operation, if no battery units 110 are connected to the buffer module 104, a battery voltage V₁ detected at the battery pack controller 116 will be 3.3 volts in the specific embodiment shown. If one battery unit 110 is connected to the buffer module 104, a battery voltage V₂ detected at the controller 116 would change to a first predetermined range, being the voltage across resistor R₂. Similarly, if a second battery unit 110 is connected to the buffer module 104, a battery voltage V₃ detected at the controller 116 would change to a second predetermined range, being the voltage across resistors R₂ and R₃ effectively connected in parallel. The same principal applies for each additional battery unit 110 connected to the buffer module 104. The battery voltage Vₙ detected at the controller 116 would be the voltage across the resistors R₂, R₃ . . . Rₙ effectively connected in parallel.

Since different battery voltage ranges can be expected from different types of battery units, comparing the detected battery voltage Vₙ against a predetermined range would enable the controller 116 to determine the type of battery unit being connected to the buffer module 104.

In the specific example shown in FIG. 1, each battery pack 102 includes two Toyota NiMH hybrid battery units 110, and each resistor R₂, R₃ . . . Rₙ in the voltage divider circuit is 100 kohm. If the controller 116 detects a battery voltage of 1650 mV (+/−75 mV), the controller 116 can determine that a single Toyota NiMH hybrid battery unit has been connected to the buffer 104. If the controller 116 detects a battery voltage of 1100 mV (+/−75 mV), the controller 116 can determine that two Toyota NiMH hybrid battery units have been connected to the buffer 104 as illustrated in FIG. 1.

In the specific example shown in FIG. 2, each battery pack 102 includes three Nissan Leaf Lithium-ion battery units 202, and each resistor R₂, R₃ . . . Rₙ in the voltage divider circuit is 715 kohm. If the controller 116 detects a battery voltage of 2895 mV (+/−75 mV), the controller 116 can determine that a single Nissan Leaf Lithium-ion battery unit has been connected to the buffer 104. If the controller 116 detects a battery voltage of 2579 mV (+/−75 mV), the controller 116 can determine that two Nissan Leaf Lithium-ion battery units have been connected to the buffer 104. If the controller 116 detects a battery voltage of 2325 mV (+/−75 mV), the controller 116 can determine that three Nissan Leaf Lithium-ion battery units have been connected to the buffer 104 as illustrated in FIG. 2.

As each buffer module 104 is capable of automatically detecting and determining the specific type of battery pack connected thereto, and deriving the battery characteristics and operating parameters to thereby control the battery charge and discharge cycles sequentially on a battery module by module basis, the battery management system 120 is capable of managing a mixture of different battery packs 102 connected to the system 120 at the same time.

Now referring to FIG. 1, the battery packs 102 are connected in parallel, and each battery pack 120 is connected to a common DC busbar 132, 134. A bi-directional inverter 136 is also provided to covert DC power from the busbar 132, 134 to AC power for powering one or more AC loads 138, as well as storing any excess AC power to the grid 142. Similarly, the inverter 136 converts AC power from the grid 142 and any excess AC power from a renewable power system such as a PV solar system 144 to DC power for charging the battery packs 102 via the common DC busbar 132, 134.

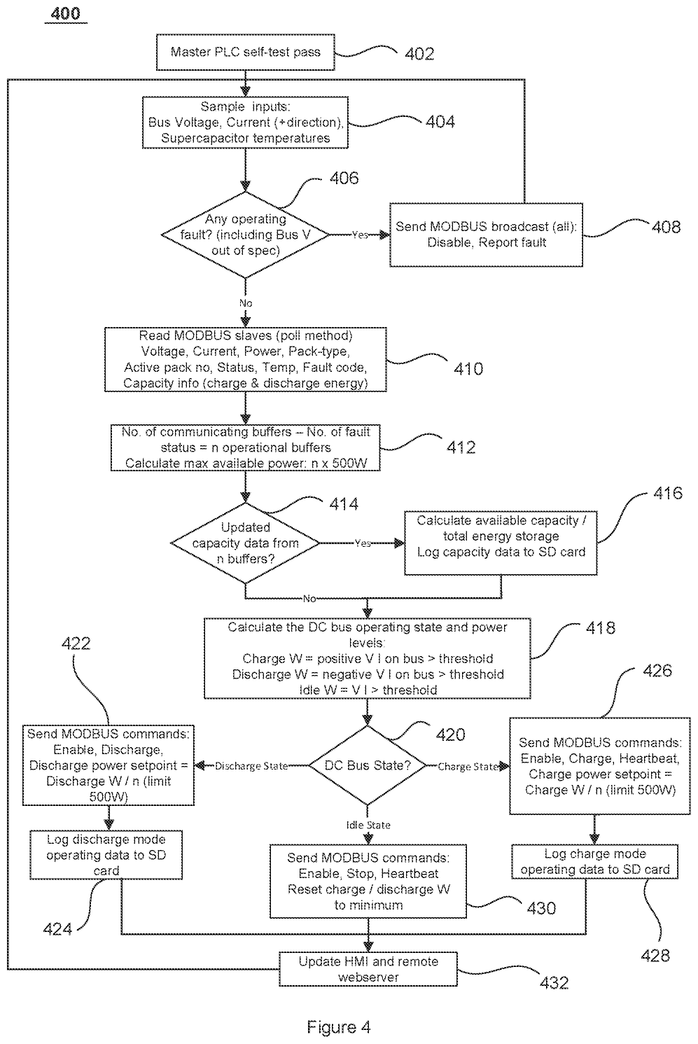

The battery system 120 further includes a system controller 140. In one embodiment, the system controller 140 is a master controller for carrying out high level decision making for the battery pack controllers 116, which are slave devices. As described in further detail below with reference to FIGS. 4 to 6, the system controller 140 matches the available power from the battery packs 102 to the AC loads. The master controller 140 also determines operating states (e.g. charge, discharge or idle state) and operating parameters (e.g. charge power, discharge power, etc) for each of the battery packs 102 based on analog inputs sampled from the DC busbar 132,134 and the battery operating parameters received from the slave devices 116. Meanwhile, the slave devices 116 periodically samples the corresponding battery pack 102 and updates the master controller 140 with battery operating parameters associated with the corresponding battery pack 102.

A pair of supercapacitors 146 are provided on the common DC busbar 132,134 for holding a voltage on the common DC busbar 132,134 generally constant during switching operations. For example, when each buffer module switches between the battery modules 108 within each battery pack 102, or when the master controller 140 switches between buffer modules 104 during operation.

Embodiments of the battery management system 120 as described herein refers to portions of the battery system 100 for interfacing and managing operations of the battery packs 102 and excludes the battery packs 102 themselves, the inverter 136 and external systems 138, 142, 144. The overall battery system 100 includes the battery management system 120, the battery packs 102 and inverter 136.

The executable software routine of the master controller 140 for executing a continuous main loop (herein referred to as method 400) of controlling high level operation the battery management system 120 will now be described with reference to the flow chart in FIG. 4.

Upon start-up, at initial step 402, the master controller 140 conducts a self-test to determine whether the controller 140 itself has any operating faults. In the specific example provided herein, the master controller is a PLC controller. However, it is understood that any suitable controller can be used. Upon determining that there are no operating faults, the method 400 proceeds to step 404.

At step 404, the master controller 140 samples inputs including the busbar voltage 148 and busbar current 152 (measurable across shunt resistor 150). A detected positive direction for the current 152 measured across the shunt resistor 150 may indicate that power is provided to the system via the inverter 136 so that the battery packs 102 can be charged. Similarly, a detected negative direction for the current 152 measured across the shunt resistor 150 may indicate that power is drawn from the system via the inverter 136 (e.g. to power one or more external AC loads) and the battery packs 102 are being discharged.

The master controller 140 also samples various digital and analog inputs, for example from the inverter 136, and temperature sensors (not shown) coupled to the supercapacitors 146 for fault detection.

At query step 406, the master controller 140 determines whether a fault has been detected in step 404. If a fault has been detected, the method 400 proceeds to step 408. If not, the method 400 proceeds to step 410.

At step 408, the master controller 140 disables operations, reports and logs the detected fault(s). The method 400 terminates until the fault(s) are rectified.

At step 410, the master controller 140 polls data from the slave devices 116. The data provided by the slave devices 116 include the voltage, current and power of the corresponding battery pack 102, type of battery pack (e.g. Toyota/Nissan), current operating status (e.g. charging or discharging), temperature, a fault code indicating whether a fault associated with the battery pack has been detected, and capacity information. Typically, the capacity information becomes available after one full charge and discharge cycle of each battery pack 102.

At step 412, the master controller 140 calculates the maximum amount of available power based on the total number of available operational battery packs 102 and buffer modules 104 (N). The total number of operational battery packs and buffer modules can be determined by subtracting the number of buffer modules 104 having a fault code associated therewith from the total number of communicating buffer modules 102 in the system 120. The maximum amount of available power in the system 120 at any point in time is 500W×N.

At query step 414, the master controller 140 polls each slave device 116 to determine whether updated capacity data is available for each battery pack 102. If so, the method 400 proceeds to step 416. If not, the method 400 proceeds to step 418.

At step 416, the master controller 140 calculates the total available energy storage capacity in the system 120 based on the updated capacity data from the slave devices 116 and logs the data. In the event that the total available energy storage capacity for a particular battery pack 102 is determined to be lower than or equal to a decommission threshold, the master 140 may determine that the battery pack 102 is at the end of its life and instruct the corresponding buffer module 104 to drain the battery module for decommissioning. As previously mentioned, each buffer module 104 includes a discharge resistor 118 for discharging the battery pack 102 at end-of-life.

At step 418, the master controller 140 determines the operating status and parameters for each buffer module 104 and corresponding battery pack 102 based on the voltage and current measurements from the DC busbar 132, 134. For example:
If a positive direction current is detected on the busbar 134, the charging power W_{charge} is determined based on V_{charge}·I_{charge}, wherein V_{charge} is the voltage detected on the busbar 132, and I_{charge} is the current detected on the busbar 134. The controller 140 also checks if W_{charge} is greater than a minimum operating threshold (e.g. ≈100W). Anything less than the minimum operating threshold would be insufficient power to charge or discharge the battery pack 102.
If a negative direction current is detected on the busbar 134, the charging power W_{discharge} is determined based on V_{discharge}·I_{discharge}, wherein V_{discharge} is the voltage detected on the busbar 132, and I_{discharge} is the current detected on the busbar 134. The controller 140 also checks whether W_{discharge} is greater than a minimum operating threshold.
In situations where the available power on the busbar 132, 134 is less than the minimum operating threshold (i.e. battery pack 102 may be fully charged or discharged, or otherwise is not charging or discharging), the corresponding buffer module 104 may be assigned an operating state as idle.

At query step 420, the master controller 140 determines the operating status of each buffer module 104 and corresponding battery pack 102. If the buffer modules 104 are to operate in a discharge state, the method 400 proceeds to step 422. If the buffer modules 104 are to operate in a charge state, the method 400 proceeds to step 426. If the buffer modules 104 are to operate be in an idle state, the method 400 proceeds to step 430.

At step 422, the master controller 140 issues commands to each operating buffer module 104 to enable discharging operations, and determines a discharge power setpoint for each of the buffer modules 104. For example, the discharge power setpoint may be W_{discharge}/N, where W_{discharge} is determined in step 418 and N is the total number of operating buffer modules 104 as determined in step 412.

At step 424, the master controller 140 logs the discharge mode operating data.

At step 426, the master controller 140 issues commands to each operating buffer module 104 to enable charging operations, and determines a charge power setpoint for each one of the buffer modules 104. For example, the charge power setpoint may be W_{charge}/N, where W_{charge} is determined in step 418 and N is the total number of operating buffer modules 104 as determined in step 412.

At step 428, the master controller 140 logs the discharge mode operating data.

At step 430, the master controller 140 issues commands to each operating buffer module 104 to stop charging and discharging operations and enter idle state, and sets the charge and discharge power values (W_{charge}, W_{discharge}) to a minimum.

At step 432, a human-machine interface and webserver (not shown) for monitoring operations of the battery system 100 can be updated with current operating data. The method 400 returns to step 404 and continues executing the method steps 404 to 430 until a fault is detected, or until the system is switched off.

The executable software routine of the slave device 116 for sampling battery operating parameters and controlling sequential charging and discharging of the battery modules 108 within each battery pack 102 will now be described with reference to the flow charts in FIGS. 5 and 6. In particular, the flow chart in FIG. 5 illustrates a start-up routine 500 for each slave device 116, and the flow chart in FIG. 6 illustrates a continuous main control loop (herein referred to as method 600) for controlling the charge and discharge cycles of the battery modules 108 for each battery pack 102.

At the start of start-up routine 500, at step 502 the corresponding buffer module 104 powers on or resets.

At query step 504, the slave device 116 determines whether a battery interface module 106 is detected. The detection of a connected battery interface module 106 indicates a corresponding battery pack has been connected to the buffer module 104. If an interface module 106 is detected, the routine 500 proceeds to step 508. If not, the routine 500 proceeds to step 506.

At step 506, slave device 116 turns on an LED indicator to indicate that a corresponding battery pack is missing, and records fault data for reporting to the master controller 140.

At step 508, the slave device 116 automatically determines the type of battery units 110 connected and the total number of battery units 110 connected in the battery pack 102 as described above with reference to FIGS. 1 to 3. The total number of battery modules 108 in the battery pack 102 can be derived from the total number of battery units 110.

At query step 510, the slave device 116 determines whether the detected battery voltage falls within the pre-determined and expected voltage ranges for the battery types as previous discussed with reference to FIGS. 1 to FIG. 3. If so, the slave device 116 records the detected battery type and the routine 500 proceeds to step 516. If not, the routine 500 proceeds to step 512.

At step 512, the slave device 116 turns on an LED indicator to indicate that a fault has been detected, and records fault data for reporting to the master controller 140.

At step 514, the slave device 116 sets the charge and discharge voltage limits according to the type of battery pack detected at steps 508 and 510. For example, a charge threshold may be 33.6 volts for a Toyota NiMh battery unit (1.40 volts per battery cell), and 24 volts for a Nissan Lithium-ion battery unit (4.00 volts per battery cell); a discharge threshold may be 25.2 volts for a Toyota NiMh battery unit (1.05 volts per battery cell), and 20.4 volts for a Nissan Lithium-ion battery unit (3.40 volts per battery cell).

At step 516, a series of fault detection tests are carried out to determine that the battery system 120 is operating as expected. For example, the tests may check operation of the switching assemblies 122 of the interface module 106, whether the DC common busbar 132, 134 is operating correctly, and that the temperature of various components such as the battery cells, DC to DC converter are within the expected operating temperature range. If a fault is detected, the routine proceeds to step 518. If not, the routine 500 proceeds to step 520.

At step 518, the slave device 116 turns on an LED indicator to indicate that a fault has been detected, and records fault data for reporting to the master controller 140.

At step 520, the slave device 116 connects the first, or a next battery module 108 via a corresponding switching assembly 122 to detect an initial battery voltage Vᵢ.

At query step 522, the slave device 116 determines whether the detected initial battery voltage Vᵢ is within an expected tolerance range for the type of battery unit detected in step 508. For example, for a Toyota NiMh battery unit, a detected initial battery voltage Vᵢ of greater than 36.0 volts (1.40 volts per cell) may indicate an over voltage fault, and a detected initial battery voltage Vᵢ of less than 24.0 volts (1.00 volts per cell) may indicate an under voltage fault. Similarly, for a Nissan Lithium-ion battery unit, a detected initial battery voltage Vᵢ of greater than 24.6 volts (4.10 volts per cell) may indicate an over voltage fault, and a detected initial battery voltage Vᵢ of less than 19.5 volts (3.25 volts per cell) may indicate an under voltage fault. If the detected initial battery voltage Vᵢ is within an expected tolerance, the routine 500 proceeds to step 524. If not, the routine 500 proceeds to step 528.

At step 524, the slave device 116 stores the open circuit battery voltage of the current battery module 108.

At query step 526, the slave device 116 determines whether the current battery module 108 is the last battery module 108 in the battery pack 102. If so, the routine 500 proceeds to step 532. If not, the routine 500 returns to step 520 and the slave device 116 sequentially connects the next battery module 108 in the pack 102.

At step 528, the slave device 116 determines that the current battery module 108 has an initial battery voltage outside the expected tolerance range and is therefore not operating according to specification. The slave device 116 disconnects the current battery module 108 via the corresponding switching assembly 112 from the battery pack 102.

At query step 530, the slave device 116 determines whether the current battery module 108 is the last battery module 108 in the battery pack 102. If so, the routine 500 proceeds to step 532. If not, the routine 500 returns to step 520 and the slave device 116 sequentially connects the next battery module 108 in the pack 102.

At step 532, the slave device 116 establishes communication with the master controller 140 via digital communication channel 154 (see FIG. 1).

At step 534, the start-up routine 500 is complete. The slave device 116 reports initial battery pack state to the master controller 140 and enters main control loop as shown in FIG. 6 to execute the method 600 of sequentially charging and discharging the battery modules 108.

Now referring to FIG. 6, at step 602, the slave device 116 receives battery type information and charge and discharge voltage limits as determined by steps 508 to 514 of the start-up routine 500 (FIG. 5).

At query step 604, the slave device 116 checks whether there is a data request from the master controller 140. If so, the method 600 proceeds to steps 606 and 608. If not, the method 600 proceeds to step 610.

At step 606, the slave device 116 receives control parameters from the master controller 140. The control parameters determine the operating status (charge/discharge/idle) of the buffer module 104 and corresponding battery pack 102, and the operating parameters, including the charge power setpoint, discharge power setpoint, end-of-life discharge via discharge resistor 118 as determined in method 400 discussed above with reference to FIG. 4.

At step 608, the slave device 116 sends battery parameters, including the parameters detected during the start-up routine 500 to a read register for polling by the master controller 140. The battery parameters include the voltage, current, power of the corresponding battery pack 102, the detected type of battery pack 102, total number of connected battery modules 108, operating status, operating temperature, associated fault codes (if any), and the most recently calculated discharge energy.

At step 610, the slave device 116 continues to sample the battery parameters and determines the average value of each of the sampled parameters. Any suitable sampling rate may be used. In one example, the slave device 116 samples the battery parameters at a rate of 100 samples per second.

At query step 612, the slave device 116 determines if one second has lapsed. If so, the method 600 proceeds to step 614. If not, the method proceeds to step 616.

At step 614, the slave device 116 calculates the average value for each sampled parameter over the 100 samples so that one average value is calculated per second. The slave device 116 also determines the discharge energy, and updates the read register with the calculated values, along with the current status and fault codes (if any).

At query step 616, the slave device 116 performs a fault check and determines whether there are any operating faults. For example, the slave device 116 may check whether the master controller 140 is on and communicating with slave device 116. If a fault is detected, the method 600 proceeds to step 618. If no fault is detected, the method 600 proceeds to step 620.

At step 618, the slave device 116 disables the bi-directional DC to DC converter 114, disconnects the battery pack 102 and DC busbar 132, 134, resets the current battery module number n to zero and updates the read register for the master controller 116.

At query step 620, the slave device 116 determines whether the current active battery module number n is zero (i.e. starting with the first battery module 108 in the battery pack 102). If so, the method 600 proceeds to step 624. If not, the method 600 proceeds to step 634.

At step 624, the slave device 116 disconnects all battery modules 108 in the battery pack 102 and sets the value of module number n to n+1.

At query step 626, the slave device 116 determines whether battery module n is disconnected in the start-up routine 500. If so, the method 600 moves to step 630. If not, the method 600 proceeds to step 628.

At step 630, the battery pack controller checks whether module n is the last module 108 in the pack 102. If so, the method 600 proceeds to step 632. If not, the method 600 returns to step 624.

At step 632, the slave device 116 disables the bi-directional DC to DC converter 114, disconnects the battery pack 102 and DC busbar 132, 134, resets the current battery module number n to zero and updates the read register for the master controller 116.

At step 628, the slave device 116 connects module n to the battery pack 102. At this stage, battery module n is the only battery module connected in the battery pack 102 for charging or discharging. Accordingly, each of the battery modules 108 in the battery pack 102 is sequentially charged and discharged one at a time.

At query step 634, (if the current battery module is not the first battery module in the battery pack 102 as determined from query step 620), the slave device 116 determines whether the current battery module n has a battery voltage or a state of charge lower than or equal to a minimum threshold (i.e. the current battery module is fully discharged), or greater than or equal to a maximum threshold (i.e. the current battery module is fully charged). If so, the method 600 moves to step 624 and the module number n is incremented to n+1, thus the slave device 116 moves on to the next battery module 108 in the battery pack 102. If not, the method 600 proceeds to query step 636.

At query step 636, the slave device 116 checks whether the corresponding buffer module 104 is operating in charge mode as determined by the master controller 140 in accordance with method 400. If so, the method 600 proceeds to step 638 to carry out charge PID control of the current battery module. If not, the method 600 proceeds to query step 640.

At query step 640, the slave device 116 checks whether the corresponding buffer module 104 is operating in discharge mode as determined by the master controller 140 in accordance with method 400. If so, the method 600 proceeds to step 638 to carry out discharge PID control of the current battery module. If not, the method 600 proceeds to step 644.

At step 644, the slave device 116 generates a signal to update an LED indicator to reflect the current operating status of the corresponding buffer module 104. The method 600 returns to query step 604 and continues to execute steps 604 to 644.

Embodiments of the invention thereby provides an improved battery management system capable of integrating multiple, parallel, ex-service hybrid or electric vehicle batteries into a larger system for the storing or time-shifting of energy in second-life battery applications.

The buffer modules are digitally controllable, capable of handling variable power (e.g. up to 500W) and may be provided at low cost. Moreover, the system 100 is scalable to any suitable size. For example, a system including 10 buffer modules can be matched to a 5 KW inverter.

Typically, the interface modules 106 are designed to be directly attachable to the corresponding ex-service battery units 110, and the plurality of switching assemblies 112 arranges battery modules 108 within each unit 110 into individual selectable, parallel modules 108. Each battery pack 102 may be expandable to include any suitable number of battery units 110, and therefore any suitable number of battery modules 108. In particular, the interface module 106 can include multiple interface boards linked together to extend the number of selectable battery modules 108 available to the buffer module 104 to increase total stored energy per buffer 104.

As previously described, each buffer module 104 may be compatible with a wide range of different types of battery packs with an operating voltage range which covers the nominal operating range for most ex-service battery packs currently on the market, e.g. between 14-36V DC. This design provides versatility and allows the battery management system 120 to be usable with any suitable type of battery pack, or any mixture of different types of battery packs in a single system.

Moreover, the automatic detection of the charge and discharge limits of the battery modules during the start-up routine as described above with reference to FIG. 3 further enables batteries of different chemistries or configurations to be safely connected to the common DC bus 132, 134. Advantageously, each of the buffer module 104 will automatically and sequentially connect only one battery module 108 at a time from the corresponding battery pack 102 during charge or discharge, removing any need to closely match parallel battery characteristics and isolating the effect of depleted cells on the overall energy storage capacity.

In the embodiments described, the constant power limit (e.g. 500W) per buffer 104 reduces the maximum current demand on each module to safe levels typically well below those used in original vehicle application. Combined with the other parallel buffer modules 104, the full output power is available to the inverter 136 regardless of individual module 108 state of charge. During a module to module transition the supercapacitor on the 48V DC bus 132, 34 holds up power on the bus 132, 134 during the short-term transition period.

As described above, all individual battery module 108 characteristics are recorded and transmitted by each slave device 116 via a digital communication bus 154 to a high-level master controller 140 that matches the load demand 138 and battery storage available to each buffer based on current state and capacity.

Accordingly, the battery management system provided herein is capable of intelligently buffering second-life batteries with different and varying characteristics (e.g. capacity, chemistry, voltage span, impedance) and automatically connecting individual battery modules 108, thereby providing a solution to problems posed by the wide variation found with ex-service hybrid or EV batteries. The present battery management system advantageously eliminates any need to pre-test, select, match, or rebuild battery packs to suit a particular energy storage system. It also prevents poor or degraded cells from impacting the overall energy storage capability.

Advantageously, the battery management system can be used in any renewable energy storage application where the it would be desirable to take advantage of low-cost, replaceable second-life batteries from variable sources. In some instances, it may have particular application to HEV and EV battery recyclers who could take advantage of renewable energy storage and time-shifting as a value-add stage prior to final recycling step.

### Interpretation

This specification, including the claims, is intended to be interpreted as follows:

Embodiments or examples described in the specification are intended to be illustrative of the invention, without limiting the scope thereof. The invention is capable of being practised with various modifications and additions as will readily occur to those skilled in the art. Accordingly, it is to be understood that the scope of the invention is not to be limited to the exact construction and operation described or illustrated, but only by the following claims.

The mere disclosure of a method step or product element in the specification should not be construed as being essential to the invention claimed herein, except where it is either expressly stated to be so or expressly recited in a claim.

The terms in the claims have the broadest scope of meaning they would have been given by a person of ordinary skill in the art as of the relevant date.

The terms “a” and “an” mean “one or more”, unless expressly specified otherwise.

Neither the title nor the abstract of the present application is to be taken as limiting in any way as the scope of the claimed invention.

Where the preamble of a claim recites a purpose, benefit or possible use of the claimed invention, it does not limit the claimed invention to having only that purpose, benefit or possible use.

In the specification, including the claims, the term “comprise”, and variants of that term such as “comprises” or “comprising”, are used to mean “including but not limited to”, unless expressly specified otherwise, or unless in the context or usage an exclusive interpretation of the term is required.

The disclosure of any document referred to herein is incorporated by reference into this patent application as part of the present disclosure, but only for purposes of written description and enablement and should in no way be used to limit, define, or otherwise construe any term of the present application where the present application, without such incorporation by reference, would not have failed to provide an ascertainable meaning. Any incorporation by reference does not, in and of itself, constitute any endorsement or ratification of any statement, opinion or argument contained in any incorporated document.

1. A battery management system for managing one or more second-life battery packs, the system comprising
one or more buffer modules, each buffer module for coupling to a corresponding battery pack, wherein each buffer module is operatively configured to determine a type of battery pack upon detection of the corresponding battery pack being coupled thereto, and
each buffer module including a battery pack controller for controlling charge and discharge cycles for each battery pack based on the type of battery pack as determined by the corresponding buffer module,
wherein each buffer module includes a bi-directional DC to DC converter for converting a voltage input from the corresponding battery pack to a predetermined system output voltage.

2. The battery management system of claim 1, wherein each battery pack controller is operatively configured to determine one or more battery parameters associated with the corresponding battery pack to determine the type of battery pack.

3. The battery management system of claim 2, wherein the battery parameters include any one or more of
an output voltage range of the corresponding battery pack, and
a number of battery modules in the corresponding battery pack.

4. The battery management system of claim 1, wherein the converter is configured to receive a voltage input from the corresponding battery pack having an operating voltage range of generally between 14 to 36 volts.

5. The battery management system of claim 1, wherein the converter is configured to provide a predetermined system output voltage of about 48 volts DC from the corresponding battery pack.

6. The battery management system of claim 1, wherein the converter is configured to provide a predetermined power output of about 500W from the corresponding battery pack.

7. The battery management system of claim 1, wherein the converter is coupled to a discharge resistor for discharging a corresponding battery pack at end of life.

8. The battery management system of claim 1, wherein each battery pack includes a plurality of battery modules, and the battery management system further comprises
one or more interface modules, each interface module being configured to interface with the battery modules of a corresponding battery pack.

9. The battery management system of claim 8, wherein each interface module includes a plurality of switching assemblies for connecting the battery modules in each corresponding battery pack to the corresponding buffer module,
wherein the battery pack controller is operatively configured to sequentially determine whether each battery module within the corresponding battery pack is defective, and disconnecting the battery module from the buffer module upon determining that the battery module is defective.

10. The battery management system of claim 8, wherein the battery pack controller determines whether each battery module is defective by determining whether the battery module has an output voltage within a predetermined voltage tolerance range.

11. The battery management system of claim 8, wherein the battery pack controller is operatively configured to sequentially charge or discharge each battery module one at a time.

12. The battery management system of claim 1, further comprising a common DC bus, wherein the battery management system is configured to
connect two or more battery packs in parallel, and
connect each battery pack to the common DC bus via the corresponding buffer module.

13. The battery management system of claim 12, further comprising one or more capacitors coupled to the common DC bus for holding a voltage on the common DC bus generally constant while switching between battery modules within each battery pack.

14. The battery management system of claim 12, further including
a system controller for determining control parameters for communication with each battery pack controller based on voltage and current values detected on the common DC bus, the control parameters including any one or more of
an operating state of the battery management system, the operating state including a charge state, a discharge state and an idle state,
a charge power setpoint for each battery pack controller, and
a discharge power setpoint for each battery pack controller.

15. The battery management system of claim 14, wherein
each battery pack controller is operatively configured to detect an operating fault associated with the corresponding battery pack or corresponding buffer module, and assign a fault status for the corresponding buffer module upon detection of the operating fault, and
the system controller is operatively configured to exclude the buffer module associated with a fault status in use.

16. The battery management system of claim 14, wherein the system controller is a master controller, and each battery pack controller is a slave device for receiving control signals from the master controller, and wherein each slave device is configured to sample the corresponding battery pack and update the master controller with battery parameters associated with the corresponding battery pack.

17. (canceled)

18. A battery system comprising
a plurality of battery packs,
a plurality of buffer modules, each buffer module being configured for coupling to a corresponding battery pack, wherein each buffer module is operatively configured to determine a type of battery pack upon detection of the corresponding battery pack being coupled thereto,
each buffer module including a battery pack controller for controlling charge and discharge cycles for each battery pack based on the type of battery pack as determined by the corresponding buffer module,
wherein each buffer module includes a bi-directional DC to DC converter for converting a voltage input from the corresponding battery pack to a predetermined system output voltage.

19. The battery system of claim 18, wherein each battery pack controller is operatively configured to determine one or more battery parameters associated with the corresponding battery pack to determine the type of battery pack, and wherein the battery parameters include any one or more of
an output voltage range of the corresponding battery pack, and
a number of battery modules in the corresponding battery pack.

20. The battery system of claim 18, wherein the DC to DC converter is coupled to a discharge resistor for discharging a corresponding battery pack at end of life.

21.-27. (canceled)

28. The battery system of claim 18, wherein at least one of the plurality of battery packs has a differing battery pack chemistry and/or topology to one or more of the other battery packs in the plurality of battery packs.
